(19) United States
(12) Patent Application Publication
(10) Pub. No.: US 2004/0032009 A1
(43) Pub. Date: Feb. 19, 2004

(54) Semicondutor wafer device

(75) Inventors: Yao-Shin Fang, Hualien (TW); Chi-Cheng Pan, Kaohsiung (TW); Kuo-Pin Yang, Kaohsiung (TW); Su Tao, Kaohsiung (TW); Sung-Ching Hung, Changhua (TW); Chun-Chi Lee, Kaohsiung (TW); Ho-Ming Tong, Taipei (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/637,695

(22) Filed: Aug. 11, 2003

(30) Foreign Application Priority Data
Aug. 13, 2002 (TW) 091212559

(51) Int. Cl. H01L 23/544

(52) U.S. Cl. 257/620

(57) ABSTRACT

A semiconductor wafer device is provided in this invention. The semiconductor wafer device includes a plurality of chips, circuits, cutting streets, and a polymer layer. The cutting streets include a plurality of longitudinal cutting streets and transverse cutting streets, which are formed between the neighboring chips, and the polymer layer is formed on the cutting streets. In addition, this invention also provides a semiconductor wafer device with a plurality of bumps formed thereon and the bumps are encompassed with a polymer layer.

### BACKGROUND OF THE INVENTION

1. Field of Invention

This invention relates to a semiconductor wafer device. More particularly, the present invention is related to a semiconductor wafer device, suitable for wafer level chip package technology.

2. Related Art

In this information explosion age, integrated circuit products are used almost everywhere in our daily life. As fabricating techniques continue to improve, electronic products having powerful functions, personalized performance and a higher degree of complexity are produced. Nowadays, most electronic products are relatively light and compact. Hence, in semiconductor production, various types of high-density semiconductor packages have been developed. Wafer level chip scale package is one of the most commonly used techniques for forming an integrated circuit package.

As shown in FIG. 1A and 1B, the semiconductor wafer device 1 includes a plurality of chips 11 and circuits (not shown) formed in each chip 11. A longitudinal cutting street 12 and a transverse cutting street 13 are formed between the neighboring chips 11. Therein, the semiconductor wafer device further includes a plurality of bumps 14 disposed onto the bonding pads 15 thereof.

The wafer level chip scale package is packaged and tested prior to the step of cutting semiconductor wafer device to separate the semiconductor wafer device into individual chips. However, as shown in FIG. 1B, when the step of cutting semiconductor wafer device is implemented by using the cutting tools, the cutting tools will cause the fringes of the chips to be cracked and the circuits to be damaged. After the step of sawing semiconductor wafer device, the fringes of the chips are easily cracked. Accordingly, the yield of the packaging products is declined and the manufacturing cost is increased.

Thus, it is an important object to provide a semiconductor wafer device to solve the mentioned-above problems.

### SUMMARY OF THE INVENTION

In view of the above-mentioned problems, an objective of this invention is to provide a semiconductor wafer device, which can prevent the fringes of the chips from being cracked and prevent the circuits from being damaged when the step of cutting the semiconductor wafer device is performed. Accordingly, it can increase the yield of the packaging products and save the manufacturing cost.

To achieve the above-mentioned objective, a semiconductor wafer device is provided, wherein the semiconductor wafer device comprises a plurality of chips, circuits and cutting streets, and a polymer layer. The circuits are formed in the chips, and the polymer layer is formed on the cutting streets. In addition, the cutting streets further comprise longitudinal streets and transverse streets, and the longitudinal street or the transverse street is formed between the neighboring chips,

Furthermore, this invention also provides a semiconductor wafer device with a plurality of bumps formed thereon. It characterized that a polymer layer is formed above the semiconductor wafer device to encompass the plurality of bumps.

Compared with conventional semiconductor wafer device, this invention provides a semiconductor wafer device having a polymer layer formed on the cutting streets to prevent the fringes of the chips from being cracked and to prevent the circuits being from damaged when the step of cutting semiconductor wafer device is performed. Thus, this invention will increase the yield of the packaging products and save manufacturing cost.

### BRIEF DESCRIPTION OF THE DRAWINGS

The invention will become more fully understood from the detailed description given herein below illustrations only, and thus are not limitative of the present invention, and wherein:

FIG. 1A is a top view of the conventional semiconductor wafer device;

FIG. 1B is a cross-sectional view of the conventional semiconductor wafer device of FIG. 1A;

FIG. 2A is a top view of a semiconductor wafer device in accordance with an embodiment of the invention;

FIG. 2B is a cross-sectional view of the semiconductor wafer device of FIG. 2A; and

FIG. 3 is a top view of a semiconductor wafer device in accordance with another embodiment of the invention.

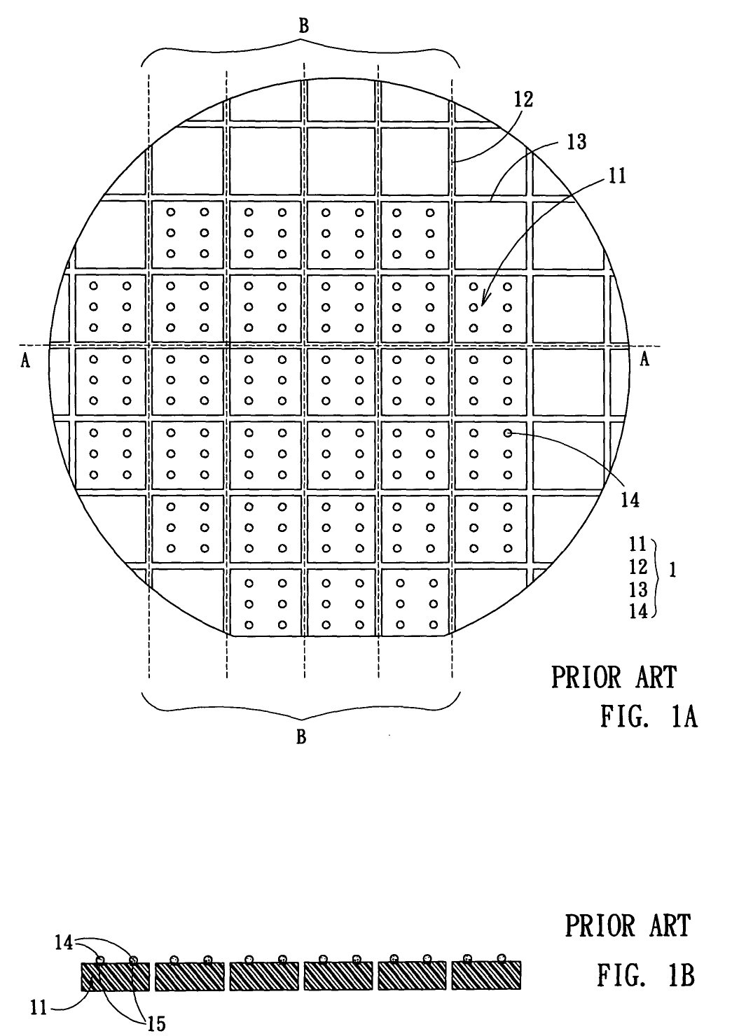

### DETAILED DESCRIPTION OF THE INVENTION

The semiconductor wafer device and the semiconductor device according to the preferred embodiment of this invention will be described herein below with reference to the accompanying drawings, wherein the same reference numbers refer to the same elements.

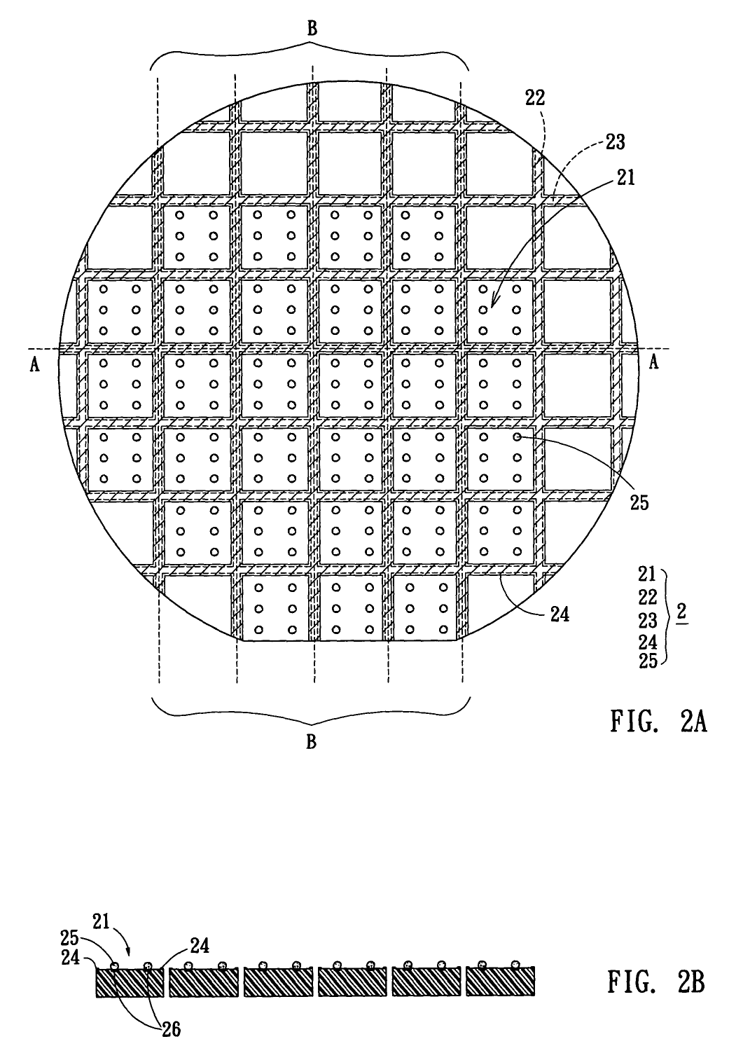

In accordance with a preferred embodiment as shown in FIG. 2A, a semiconductor wafer device 2 includes a plurality of chips 21, circuits (not shown) formed in each chip, cutting streets 22 and 23, and a polymer layer 24. The circuits are formed in each chip and the polymer layer 24 is formed on the cutting streets 22 and 23. In addition, the cutting streets 22 and 23 further comprise longitudinal streets 22 and transverse streets 23, and the longitudinal street or the transverse street is formed between the neighboring chips 21, and

In this preferred embodiment, the polymer layer 24 is formed on the longitudinal cutting streets 22 and transverse cutting streets 23 through the method of screen-printing. Therein, stencil and squeegee are utilized in the method of screen-printing to have polymer material disposed on a predetermined area according to destined patterns. In addition, the polymer material can be formed through another method, for example a conventional lithography method in semiconductor manufacturing process.

As mentioned above and shown in FIG. 2B, the purpose of disposing the polymer layer 24 on the semiconductor wafer device 2 is to prevent the fringes of the chips 21 from being cracked and to prevent the circuits from being damaged in the duration of cutting the semiconductor wafer device 2.

Referring to FIG. 2A, the area of the polymer layer 24 of this preferred embodiment is larger than the areas of the plurality of longitudinal cutting streets 22 and transverse cutting streets 23. Namely, the longitudinal cutting street 22 and the transverse cutting street 23 are entirely covered by the polymer layer. Accordingly, it can prevent the fringes of the chips 21 from being cracked in the duration of cutting the semiconductor wafer device 2.

Besides, as shown in FIG. 2A and 2B, there are a plurality of bumps 25 further provided on the bonding pads 26 of each chips 21.

Those who are familiar with the technology of wafer level chip scale package should realize that a predetermined circuits layout is performed in a semiconductor wafer device and then a plurality of bumps are formed on the semiconductor wafer device. Afterwards, a plurality of chips are formed in the process of cutting the semiconductor wafer device. Sequentially, a packaging process is performed

In this preferred embodiment, the polymer layer 24 is disposed on the longitudinal cutting streets 22 and transverse cutting streets 23 of the semiconductor wafer device 2 through the method of screen-printing and then cured. Next, a plurality of bumps 25 are formed on the bonding pads 26 of the semiconductor wafer device 2 via plating, printing or a ball-mounting method. For example, solder bumps and gold bumps can be utilized as interconnection between the semiconductor wafer device and external circuits. In addition, the polymer layer 24 can be formed in the sequence of the process of forming bumps 25. Finally, cutting the semiconductor wafer device 2 along the longitudinal streets 22 and the transverse streets 23 is performed.

Furthermore, in this preferred embodiment, the polymer layer 24 can be formed on the bonding pads 26 of the chips 21. Specifically, the polymer layer 24 can be formed between the bonding pads 26 and the corresponding bumps 25 and includes a flux material to enhance the ability of bonding the bumps 25 to the bonding pads 26. From another point of view, the polymer layer 24 will be formed to encompass the bumps 25 so as to be a buffer layer to prevent the bumps 25 from being damaged after the reflow process. Furthermore, the bumps include conductive bumps and the polymer layer at least exposes one of the bumps for electrically connecting external circuits.

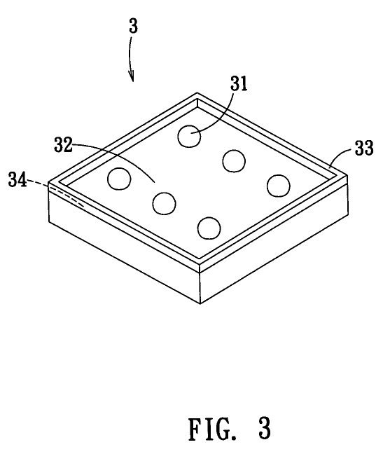

Besides, as shown in FIG. 3, this invention also provides a semiconductor device 3 having a plurality of bumps 31 formed on the bonding pads (not shown) which is located on the active surface 32. It is characterized in that a polymer layer 33 is formed at a fringe 34 of the active surface 32 of the semiconductor device 3.

It should be noted that the function and characterization of the semiconductor device 3 according to this invention is the same as the ones specified in the semiconductor wafer device 1.

This invention is related to a semiconductor wafer device with a polymer layer formed on the cutting streets. In such a manner, the fringes of the chips formed in the semiconductor wafer device can be prevented from being cracked and the circuits from being damaged and shorted. Thus, the yield of the packaging products can be increased and the manufacturing cost will be saved.

Although the invention has been described in considerable detail with reference to certain preferred embodiments, it will be appreciated and understood that various changes and modifications may be made without departing from the spirit and scope of the invention as defined in the appended claims.

What is claimed is:

1. A semiconductor wafer device, comprising:
a plurality of chips;
a plurality of cutting streets, each cutting street formed between the neighboring chips; and
a polymer layer formed on the cutting streets.

2. The semiconductor wafer device of claim 1, wherein the cutting streets comprise a plurality of longitudinal cutting streets and a plurality of transverse cutting streets.

3. The semiconductor wafer device of claim 1, wherein the area of the polymer layer is larger than the areas of the cutting streets.

4. The semiconductor wafer device of claim 1, wherein the cutting streets are entirely covered by the polymer layer.

5. The semiconductor wafer device of claim 1, wherein each chip further comprises a plurality of boding pads.

6. The semiconductor wafer device of claim 5, further comprising a plurality of bumps formed on the corresponding bonding pads.

7. A semiconductor wafer device, comprising:
a plurality of chips;
a plurality of bumps formed on the chips; and
a polymer layer encompassing the bumps.

8. The semiconductor wafer device of claim 7, wherein each chip further comprises a plurality of boding pads for electrically connecting to the bumps.

9. The semiconductor wafer device of claim 7, wherein the polymer layer at least exposes one of the bumps.

10. The semiconductor wafer device of claim 7, wherein the polymer layer further comprises a flux material.

11. A semiconductor device, comprising:
an active surface;
a plurality of bonding pads formed on the active surface;
a plurality of bumps formed on the corresponding bonding pads; and
a polymer layer formed at a fringe of the active surface.

12. The semiconductor device of claim 11, wherein the bumps include conductive bumps.
